(19) United States
(12) Patent Application Publication
(10) Pub. No.: US 2008/0048176 A1
(43) Pub. Date: Feb. 28, 2008

(54) Semiconductor device and method for fabricating the same

(76) Inventors: Kenji Orita, Osaka (JP); Yasuyuki Fukushima, Osaka (JP)

Correspondence Address: MCDERMOTT WILL & EMERY LLP, 600 13TH STREET, NW, WASHINGTON, DC, 20005-3096, US

(21) Appl. No.: 11/892,708

(22) Filed: Aug. 27, 2007

(30) Foreign Application Priority Data
Aug. 28, 2006 (JP) 2006-230405

(51) Int. Cl. H01L 29/06; H01L 21/00

(52) U.S. Cl. 257/22; 438/29; 257/E29.005

(57) ABSTRACT

A semiconductor device includes a semiconductor superlattice layer and a semiconductor multilayer. The semiconductor superlattice layer has periodic concave-convex shapes, and a plurality of semiconductor films each having bent portions in accordance with the concave-convex shapes are stacked in the semiconductor superlattice layer. The semiconductor multilayer is formed so as to cover the concave-convex shapes and includes an active layer.

### CROSS-REFERENCE TO RELATED APPLICATIONS

This application claims priority under 35 U.S.C. §119 on Patent Application No. 2006-230405 filed in Japan on Aug. 28, 2006, the entire contents of which are hereby incorporated by reference.

### BACKGROUND OF THE INVENTION

The present invention relates to a semiconductor device and a method for fabricating the same, and more particularly, it relates to a semiconductor device such as a semiconductor light emitting diode, a semiconductor laser diode, a bipolar transistor or a field effect transistor.

It has been conventionally difficult to attain high luminous efficiency in light emitting devices such as a light emitting diode (LED) and a semiconductor laser diode for emitting light of a wavelength band from ultraviolet light to blue or green light, but these light emitting devices are now being earnestly studied and developed by using nitride-based compound semiconductors typified by GaN. In particular, since an LED is more easily fabricated than a semiconductor laser diode and has a longer life time than an incandescent lamp or a fluorescent tube, an LED using a nitride-based compound semiconductor is expected as a light source of lighting equipment. In order to realize lighting equipment with a surface light source by using a large number of LEDs each corresponding to a point light source, it is indispensable to reduce the cost of the LEDs. In a conventional nitride-based compound semiconductor LED, however, an expensive sapphire substrate with a small aperture is used for crystal growth, and hence, it is difficult to reduce the cost.

Therefore, attention is now being paid to a technique to grow a crystal of a nitride-based compound semiconductor on a silicon (Si) substrate inexpensively available with a large aperture. In order to put an LED using a nitride-based compound semiconductor grown on a Si substrate to practical use, it is significant to overcome the following problem: A difference in the lattice constant between a nitride-based compound semiconductor and a Si substrate is much larger than a difference from a sapphire substrate. Therefore, crystal defects such as threading dislocations are caused in a density at a level of 10⁹/cm² when a light emitting layer is formed on a sapphire substrate while the density is increased to a level of 10¹¹/cm² when a light emitting layer is formed on a Si substrate. Since crystal defects, each of which functions as the center of non-radiative recombination, are present in the light emitting layer in such a high density, the internal quantum efficiency is largely degraded in the light emitting layer formed on the Si substrate.

In a technique developed for overcoming this problem, a multilayered film of gallium nitride (GaN) and aluminum nitride (AlN) is used as a buffer layer formed before growing a light emitting layer (see, for example, B. Zhang, et al., “Japanese Journal of Applied Physics”, 2003, vol. 42, pp. L226-L228).

FIG. 12 shows an example of a conventional nitride-based compound semiconductor LED using a buffer layer made of a multilayered film of GaN and AlN. As shown in FIG. 12, the conventional nitride-based compound semiconductor LED includes a buffer layer 1005 formed on a Si substrate 1001. The buffer layer 1005 includes an AlN layer 1002 with a thickness of 2.5 nm, an Al_{0.3}Ga_{0.7}N layer 1003 with a thickness of 30 nm and a multilayered film 1004 including twenty pairs each of an AlN film with a thickness of 5 nm and a GaN film with a thickness of 25 nm. An LED structure 1010 is formed on the buffer layer 1005. The LED structure 1010 includes an n-type cladding layer 1006 made of GaN and having a thickness of 0.2 μm, a light emitting layer 1007 having a multiple quantum well (MQW) structure composed of fifteen pairs each of a well layer made of undoped In_{0.18}Ga_{0.82}N and having a thickness of 3 nm and a barrier layer made of undoped In_{0.0}Ga_{0.99}N and having a thickness of 5 nm, an overflow suppressing layer 1008 made of Al_{0.10}Ga_{0.90}N and having a thickness of 20 nm, and a p-type contact layer 1009 made of GaN and having a thickness of 0.2 μm successively formed. A transparent P electrode 1011 made of a nickel (Ni) thin film and a gold (Au) thin film and a P bonding electrode 1012 made of Ni and Au are successively formed on the p-type contact layer 1009. On a back surface of the Si substrate 1001, an N electrode 1013 made of gold-tin alloy and gold is formed.

Even when such a buffer layer is used, however, a light emitting layer grown on a Si substrate still has threading dislocations in a high density at a level of 10¹⁰/cm². Therefore, the internal quantum efficiency of the light emitting layer is still as low as 50% or less of that attained by using a sapphire substrate.

Moreover, there is a problem that light extraction efficiency for extracting light from an LED is low when the aforementioned conventional structure is employed. The light extraction efficiency is efficiency for emitting light generated in a light emitting layer out of an LED. There are two reasons for the low light extraction efficiency, that is, light absorption by the Si substrate and total reflection on the surface of the LED. Since a Si substrate absorbs light of a wavelength shorter than infrared light (of a wavelength of 1.1 μm), blue or green light generated in the light emitting layer 1007 and propagated to the substrate is absorbed by Si and hence cannot be taken out of the LED.

The total reflection on the surface of an LED is caused because a semiconductor has a larger refractive index than the air. When the incident angle (which is 0 degrees in vertical incidence) against the interface between a semiconductor and the air is larger than a critical angle, this incident light is totally reflected on the interface and is confined within the LED to be ultimately absorbed and converted into heat by an electrode, a crystal defect or the like. For example, GaN has a refractive index of 2.45 against light of a wavelength of 450 nm, and hence, the total reflection critical angle is as small as 23 degrees. In this case, the rate of light that is emitted from an active layer and is not totally reflected but taken out of the LED is approximately merely 4% per light emitting face.

Furthermore, threading dislocations present in a high density can be a factor to degrade the characteristic not only in an LED but also in a semiconductor laser diode, a transistor, a diode or the like.

### SUMMARY OF THE INVENTION

An object of the invention is solving the aforementioned conventional problems so as to realize a semiconductor device in which the density of defects such as threading dislocations is low.

In order to achieve the object, the semiconductor device of this invention is formed on a substrate having periodically formed concave-convex shapes.

Specifically, the semiconductor device of this invention has periodic concave-convex shapes and includes a semiconductor superlattice layer in which a plurality of thin films having bent portions according to the concave-convex shapes are stacked and a semiconductor multilayer formed so as to cover the concave-convex shapes and including an active layer.

In the semiconductor device of this invention, regions of the semiconductor multilayer formed in portions corresponding to the concave-convex shapes are formed as low-defect regions in which the threading dislocation density is low. Accordingly, the electric characteristic of the semiconductor device is improved. In particular, when the semiconductor device is a light emitting device, the internal quantum efficiency of a light emitting layer included therein is improved.

The method for fabricating a semiconductor device of this invention includes the steps of (a) preparing a substrate having periodic recesses or projections; (b) forming a semiconductor superlattice layer on the substrate along the recesses or projections; and (c) forming a semiconductor multilayer including an active layer on the semiconductor superlattice layer.

In the method for fabricating a semiconductor device of this invention, a semiconductor superlattice layer having concave-convex shapes can be easily formed. Furthermore, a semiconductor multilayer having a low-defect region with a low threading dislocation density can be formed. Accordingly, a semiconductor device with an improved characteristic can be easily fabricated.

### BRIEF DESCRIPTION OF THE DRAWINGS

FIG. 1 is a cross-sectional view of a semiconductor device according to Embodiment 1 of the invention.

FIGS. 2A, 2B, 2C and 2D are perspective views for showing procedures in fabrication of the semiconductor device of Embodiment 1.

FIGS. 3A and 3B are electron microscope photographs for showing the cross-sectional structure of the semiconductor device of Embodiment 1.

FIGS. 4A and 4B are diagrams of cathode luminescence images of the semiconductor device of Embodiment 1, and specifically, FIG. 4A shows a cathode luminescence image of a light emitting layer formed on a flat region and FIG. 4B shows a cathode luminescence image of a light emitting layer formed on a two-dimensional periodic structure.

FIG. 5 is a graph for showing the correlation between a cathode luminescence integrated intensity of the semiconductor device of Embodiment 1 and a period of the two-dimensional periodic structure.

FIG. 6 is an electron microscope photograph for showing a two-dimensional periodic structure of the semiconductor device of Embodiment 1.

FIGS. 7A and 7B are diagrams for showing device characteristics of the semiconductor device of Embodiment 1 of the invention, and specifically, FIG. 7A is a graph for showing the correlation between a bias voltage and a forward current and FIG. 7B is an optical microscope photograph for showing a light emitting state.

FIG. 8 is a graph for showing electroluminescence spectra of the semiconductor device of Embodiment 1.

FIG. 9 is a graph for showing the correlation between the optical output of the semiconductor device of Embodiment 1 and the period of the two-dimensional periodic structure.

FIG. 10 is a cross-sectional view of a semiconductor device according to Embodiment 2 of the invention.

FIG. 11 is a cross-sectional view of a semiconductor device according to Embodiment 3 of the invention.

FIG. 12 is a cross-sectional view of a conventional semiconductor device.

### DETAILED DESCRIPTION OF THE INVENTION

### Embodiment 1

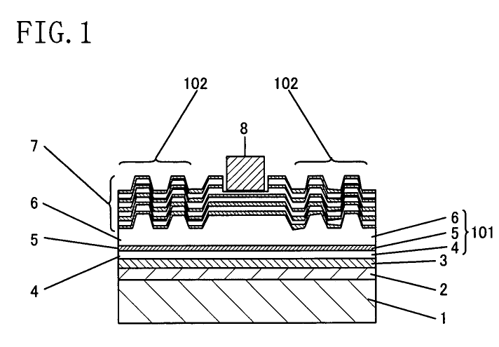

Embodiment 1 of the invention will now be described with reference to the accompanying drawings. FIG. 1 shows the cross-sectional structure of a semiconductor device according to Embodiment 1. As shown in FIG. 1, the semiconductor device of this embodiment is an LED. In the semiconductor device, a semiconductor multilayer 101 is bonded to a holding substrate 1 made of Si with a solder layer 2 and a P electrode 3, that is, a reflection electrode, sandwiched therebetween. A semiconductor superlattice layer 7 is formed on the semiconductor multilayer 101.

The solder layer 2 is preferably made of a material easily fused between metals, such as lead (Pb), tin (Sn), indium (In) or gold (Au). In this embodiment, a solder material utilizing eutectic of Sn and Au is used. As the P electrode 3 of this embodiment, a multilayered film of palladium (Pd), platinum (Pt) and gold (Au) is used. In this case, reflectance of light of a wavelength of 450 nm entering the interface between GaN and Pd from a side of the GaN is 46%, which is higher than reflectance of the light (vertical incident) on the interface between GaN and Si, that is, 10%.

In the semiconductor multilayer 101, a p-type contact layer 4 made of GaN doped with magnesium (Mg) (i.e., Mg-doped GaN) and having a thickness of 0.1 μm, an overflow suppressing layer (not shown) made of Mg-doped AlGaN and having a thickness of 20 nm, a light emitting layer 5 having a MQW structure including five pairs each of a well layer of undoped InGaN with a thickness of 3 nm and a barrier layer of Si-doped GaN with a thickness of 5 nm, and an n-type cladding layer 6 made of Si-doped GaN and having a thickness of 0.2 μm are stacked in this order above the P electrode 3.

The semiconductor superlattice layer 7 includes a multilayered film including twenty pairs each of a thin film of Si-doped AlN with a thickness of 5 nm and a thin film of Si-doped GaN with a thickness of 25 run; a thin film of undoped Al_{0.3}Ga_{0.7}N with a thickness of 30 nm (not shown); and a thin film of undoped AlN with a thickness of 40 nm (not shown). The semiconductor superlattice layer 7 works as a buffer layer in forming the semiconductor multilayer 101 as described below.

In the semiconductor superlattice layer 7, a two-dimensional periodic structure 102 in the periodic concave-convex shapes is formed. The concave-convex shapes are formed because each thin film included in the semiconductor superlattice layer 7 itself has bent portions. In other words, each thin film included in the semiconductor superlattice layer 7 is continuously formed without breaking at each irregularity. A method for forming such a two-dimensional periodic structure 102 will be described later.

The surface of the semiconductor superlattice layer 7 works as a light emitting face, and the two-dimensional periodic structure 102 functions as a photonic crystal, that is, a two-dimensional periodic diffraction grating. In order to realize low contact resistance, an N electrode 8 is formed in a region where the undoped Al_{0.3}Ga_{0.7}N layer and the undoped AlN layer are removed so as to expose the multilayered film. In order to reduce the contact resistance, the N electrode 8 is preferably made of a metal with a low work function, such as titanium (Ti) or aluminum (Al). In this embodiment, the N electrode 8 is made of a multilayered film of Ti, Pt and Au.

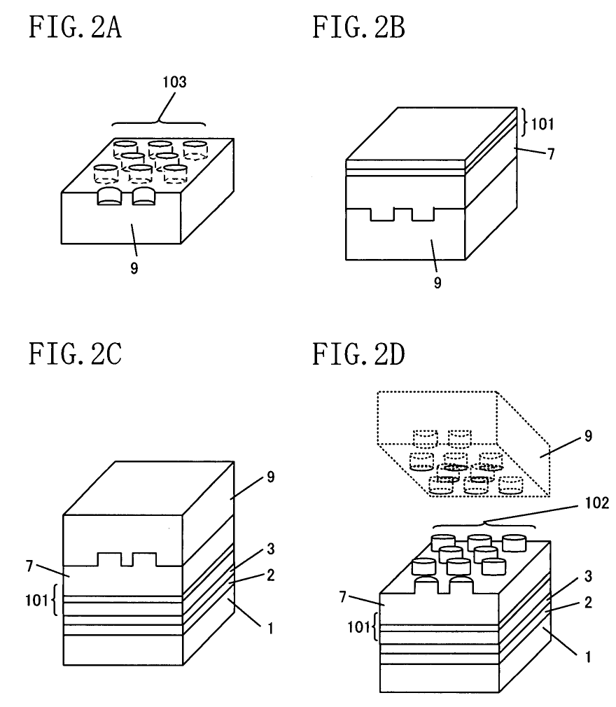

FIGS. 2A through 2D are diagrams for showing the outline of fabrication process for the semiconductor device of this embodiment. First, as shown in FIG. 2A, a two-dimensional periodic structure 103 is formed in a surface portion of a crystal growing substrate 9 of Si. Specifically, the two-dimensional periodic structure 103 may be recesses or projections formed in or on the crystal growing substrate 9. In this embodiment, the two-dimensional periodic structure 103 is formed as recesses having a depth of 50 nm and two-dimensionally arranged. This arrangement is hexagonally asymmetric (namely, the recesses are arranged in the form of an equilateral triangle), and the period is constant in a region corresponding to one LED.

Next, as shown in FIG. 2B, a buffer layer corresponding to a semiconductor superlattice layer 7 is formed on the crystal growing substrate 9 having the two-dimensional periodic structure 103. The buffer layer is obtained by forming a thin film of undoped AlN and a thin film of undoped Al_{0.3}Ga_{0.7}N and then alternately stacking a thin film of Si-doped AlN and a thin film of Si-doped GaN. Since the semiconductor superlattice layer 7 is formed on the crystal growing substrate 9 having the two-dimensional periodic structure 103, the thin films included in the semiconductor superlattice layer 7 are formed along recesses of the crystal growing substrate 9. Accordingly, the semiconductor superlattice layer 7 is provided with periodic concave-convex shapes, and each thin film included in the semiconductor superlattice layer 7 has step portions corresponding to the concave-convex shapes.

Subsequently, a light emitting layer 5, an overflow suppressing layer and a p-type contact layer 4 are successively formed on the buffer layer as a semiconductor multilayer 101. For growing these crystals, MOCVD (metal-organic chemical vapor deposition), MBE (molecular beam epitaxy) or the like can be employed, and the MOCVD is employed in this embodiment. The conditions for growing the crystal for the light emitting layer 5 are set so that the center wavelength of PL (photoluminescence) spectra emitted from the light emitting layer 5 can be 450 nm.

Furthermore, as shown in FIG. 2C, the semiconductor multilayer 101 is bonded to a holding substrate 1 with a P electrode 3 corresponding to a reflection electrode and a solder layer 2 sandwiched therebetween. Next, as shown in FIG. 2D, the crystal growing substrate 9 is removed through low-damage process. In this process, a two-dimensional periodic structure 102 is simultaneously formed in a surface portion of the semiconductor multilayer 101. As the low-damage process, wet etching, non-plasma dry etching or the like can be employed. The wet etching may be performed by using, for example, a mixed aqueous solution of hydrofluoric acid (HF) and nitric acid (HNO₃) or a potassium hydroxide (KOH) aqueous solution. The non-plasma dry etching may be performed by using a hydrochloric acid (HCl) gas or a chlorine trifluoride (ClF₃) gas. In this embodiment, the non-plasma dry etching using a ClF₃ gas is employed. Ultimately, although not shown in the drawing, an N electrode 8 is formed on the superlattice layer 7, and thus, the LED is completed.

According to the structure of the semiconductor device shown in FIG. 1 and the fabrication method for the semiconductor device shown in FIGS. 2A through 2D, a propagating direction of threading dislocations is bent through the crystal growth in the two-dimensional periodic structure 102, so that threading dislocations reaching the light emitting layer 5 are periodically distributed, and hence, a low-defect region having a low threading dislocation density is formed. In this region with a low threading dislocation density, the internal quantum efficiency of the light emitting layer can be improved. Now, the characteristics of the semiconductor device of this embodiment will be specifically described.

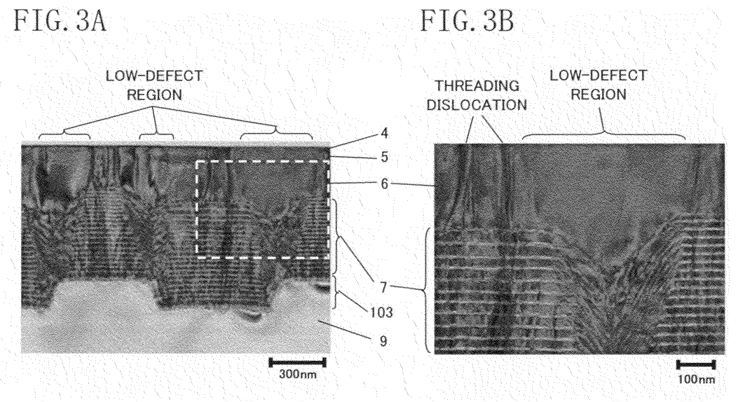

FIGS. 3A and 3B are transmission electron microscope (TEM) photographs of a semiconductor superlattice layer 7 and a semiconductor multilayer 101 grown on a crystal growing substrate 9 having a two-dimensional periodic structure 103 (where recesses are arranged at a period of 0.8 μm). FIG. 3A shows a global photograph also including the crystal growing substrate 9 and FIG. 3B shows an enlarged photograph of an area surrounded with a broken line in FIG. 3A.

It is understood from FIGS. 3A and 3B that the semiconductor superlattice layer 7 is grown while keeping the cross-sectional structure of the two-dimensional periodic structure 103. In other words, a portion of the semiconductor superlattice layer 7 formed on the sidewall of each recess of the crystal growing substrate 9 is formed as a step portion, on which the crystal is grown in a direction inclined from the vertical direction to the crystal growing substrate 9. Owing to this inclined growth, the propagating direction of the threading dislocations is bent. Therefore, there arises a phenomenon that threading dislocations having different screw directions encounter each other to disappear or that threading dislocations disappear while propagating on a heterojunction interface included in the semiconductor superlattice layer 7. As a result, the density of threading dislocations reaching the light emitting layer 5 is largely reduced in a region on the sidewall of each recess of the crystal growing substrate 9.

In the case where the light emitting layer 5 is formed on a flat crystal growing substrate under the same conditions as in this embodiment, the threading dislocation density in the light emitting layer 5 is 2×10¹⁰/cm². On the other hand, in the case where the light emitting layer 5 is formed on a crystal growing substrate having the two-dimensional periodic structure 103, the threading dislocation density in the light emitting layer 5 is 6×10⁹/cm², which is lower by 30% than that obtained in the light emitting layer formed on the flat substrate. The threading dislocation density can be further reduced by optimizing the diameter of each recess included in the two-dimensional periodic structure, the structure such as the inclined angle of the sidewall of or the depth of the recess and the crystal growth conditions.

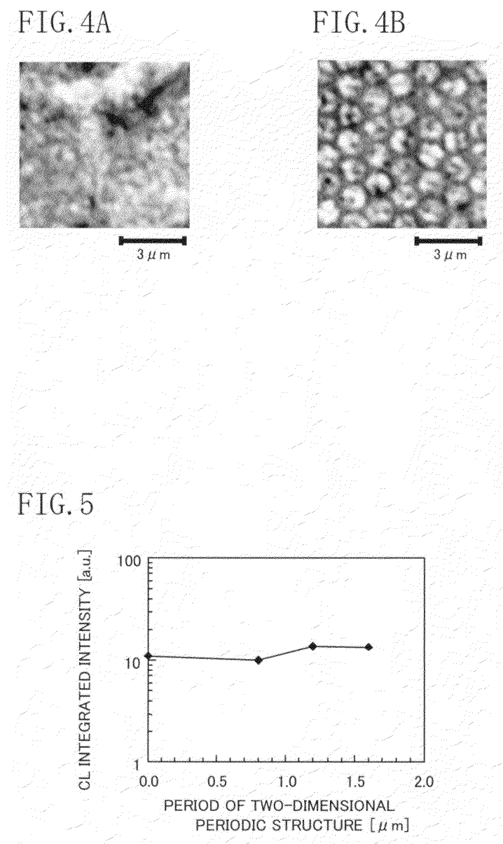

FIGS. 4A and 4B show cathode-luminescence (CL) images of the semiconductor device of this embodiment, and specifically, FIG. 4A shows an image obtained by forming a light emitting layer on a flat region and FIG. 4B shows an image obtained by forming a light emitting layer on a two-dimensional periodic structure 103 (where recesses are arranged at a period of 1.2 μm). A sample observed in each of these drawings is a wafer on which the crystal growth is stopped after forming layers up to the light emitting layer 5 in the aforementioned manner without growing the overflow suppressing layer and the p-type contact layer 4. A dark portion in a CL image corresponds to a region where a crystal defect such as a threading dislocation functions as the center of non-radiative recombination.

As is understood from FIG. 4A, dark portions and bright portions are randomly distributed in the light emitting layer formed on the flat region. On the other hand, in the light emitting layer formed on the two-dimensional periodic structure, ring-shaped bright portions are two-dimensionally and periodically arranged as shown in FIG. 4B. The period of the arrangement of the ring-shaped bright portions is the same as the period of the two-dimensional periodic structure. In other words, in the light emitting layer grown on the two-dimensional periodic structure, a low-defect region is formed so as to cyclically fringe the sidewall of each recess.

It is understood from the aforementioned images that the luminous distribution in the light emitting layer 5 can be changed into a periodic distribution through the bending and the density reduction of threading dislocations described above. Furthermore, a ring-shaped bright portion obtained on the two-dimensional periodic structure means that the luminous intensity is higher than in a bright portion obtained on the flat region.

FIG. 5 shows CL integrated intensity measured in the semiconductor device of this embodiment. In FIG. 5, the ordinate indicates the CL integrated intensity and the abscissa indicates the period of the two-dimensional periodic structure 103 provided in the crystal growing substrate 9. The period herein means a distance between the centers of adjacent recesses, and a period of 0 (zero) means that no recess is provided. As shown in FIG. 5, the CL integrated intensity of the light emitting layer 5 grown on the two-dimensional periodic structure 103 is improved in a range of the period of the two-dimensional periodic structure 103 exceeding 1 μm. This reveals that the internal quantum efficiency of the light emitting layer 5 is improved in this range.

The CL integrated intensity exemplified in FIG. 5 is improved in the range of the period of the two-dimensional periodic structure exceeding 1 μm. The threading dislocations are, however, influenced not only by the period of the two-dimensional periodic structure but also, for example, by the crystal growth conditions for the semiconductor multilayer. Therefore, the threading dislocations can be further reduced by combining the period and the structure of the two-dimensional periodic structure and the crystal growth conditions and the like for the semiconductor multilayer, so as to further improve the internal quantum efficiency. Furthermore, even when the period of the two-dimensional periodic structure is smaller than 1 μm, the threading dislocation density can be reduced so as to improve the internal quantum efficiency.

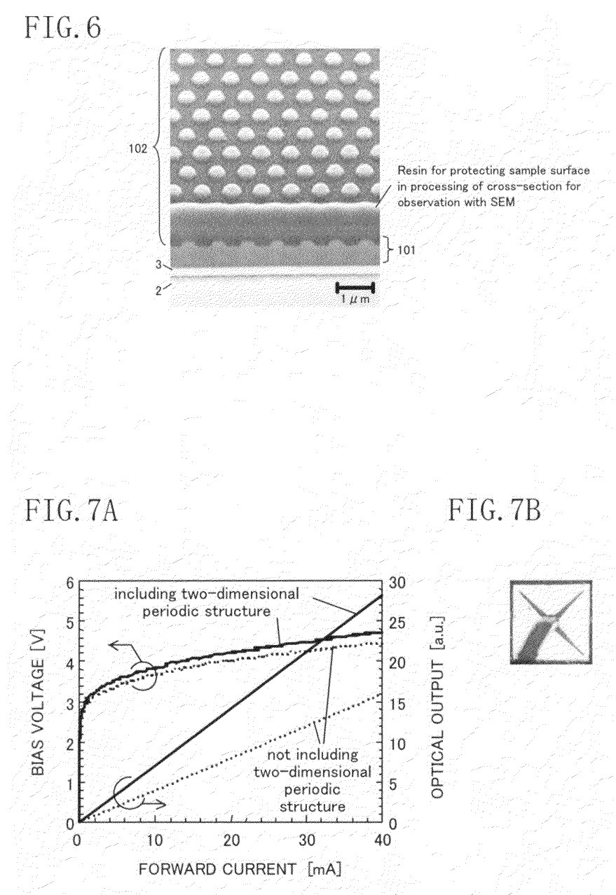

FIG. 6 shows a scanning electron microscope (SEM) photograph of the surface of the semiconductor device of this embodiment. The recess pattern of the crystal growing substrate (namely, the two-dimensional periodic structure 103) is inverted to be transferred as column-shaped projections. Thus, it is understood that the two-dimensional periodic structure 102 is formed in the surface portion of the semiconductor device. Also, it is obvious that no cracks are caused in the semiconductor multilayer 101.

When the two-dimensional periodic structure 102 thus formed in the surface portion of the semiconductor device functions as a photonic crystal having a diffraction effect, the efficiency for extracting light from the active layer can be expected to improve. In order to efficiently cause diffraction, the period of the two-dimensional periodic structure 102 is preferably not less than one time and not more than twenty times of the emission wavelength of the semiconductor multilayer. Incidentally, in the case where the emission wavelength in vacuum is 450 nm and a semiconductor has a diffractive index of 3, the emission wavelength obtained in the semiconductor is 150 nm.

In the case where the period of the two-dimensional periodic structure 102 is shorter than this range, the change of the propagating angle through the diffraction is so large that the radiation angle obtained after the diffraction is larger than the critical refraction angle. Therefore, light confined within a semiconductor device cannot be taken out due to the total reflection. Accordingly, the efficiency for extracting light cannot be improved. Alternatively, in the case where the period of the two-dimensional periodic structure 102 is longer than this range, the change of the propagating angle is small and the diffraction efficiency is also lowered. Accordingly, the light extraction efficiency cannot be improved.

FIG. 7A shows a current-voltage (I-V) characteristic and a current-optical output (I-L) characteristic of an LED of this embodiment in which a two-dimensional periodic structure (with a period of 0.8 μm) is transferred in a surface portion. The optical output of the LED including the two-dimensional periodic structure is improved by 70% as compared with an LED having a flat surface. This seems to be because the two-dimensional periodic structure functions as a photonic crystal so as to improve the light extraction efficiency.

On the other hand, a difference in the I-V characteristic caused by using the two-dimensional periodic structure is small. In other words, the electric characteristic is not lowered even when a semiconductor multilayer is grown on the two-dimensional periodic structure. FIG. 7B is an optical microscope photograph obtained with a current injected into the LED having the two-dimensional periodic structure 102. It is understood that the whole device uniformly emits blue light.

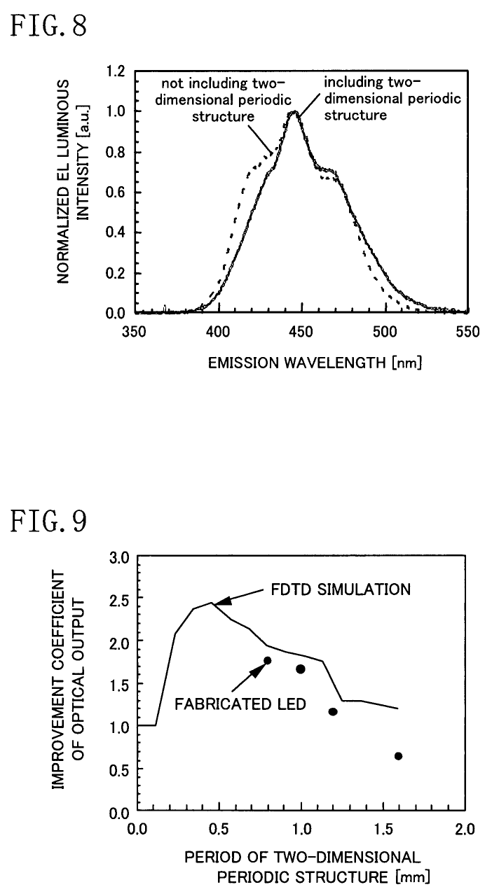

FIG. 8 shows electroluminescence (EL) spectra obtained by injecting a current into the LED. The center wavelength and the full width at half maximum of the spectra are minimally changed even when the two-dimensional periodic structure is used although a slight change is caused by interference caused by multiple reflection between the surface of the LED and the interface between the p-type contact layer 4 and the P electrode 3. It is obvious also from this data that the two-dimensional periodic structure 102 does not affect the characteristics such as the emission wavelength.

FIG. 9 shows an effect to improve the light extraction efficiency (an optical output improving effect) attained by the diffraction of the two-dimensional periodic structure obtained through theoretical calculation of light propagation. For the theoretical calculation, simulation performed by an FDTD (finite-difference time-domain) method is employed. It is understood that the result of the theoretical calculation accords with a result obtained in the LED fabricated in this embodiment. Accordingly, it can be determined that the improvement of the optical output of the LED including the two-dimensional periodic structure 102 is attained as a result of improving the light extraction efficiency by using the two-dimensional periodic structure 102. Also, from the viewpoint of the improvement of the light extraction efficiency, the period of the two-dimensional periodic structure is preferably approximately 0.2 μm through 1.2 μm.

As described so far, an LED with high internal quantum efficiency and high light extraction efficiency can be inexpensively provided according to this embodiment. Furthermore, although description of this embodiment has been made on a nitride-based compound semiconductor that is a chemically stable material and is difficult to subject to microprocessing because a two-dimensional periodic structure obtained from the material has a small period in accordance with the emission wavelength, the present invention is applicable to a semiconductor device for emitting infrared or red light using AlGaAs or AlGaInP as a semiconductor.

### Embodiment 2

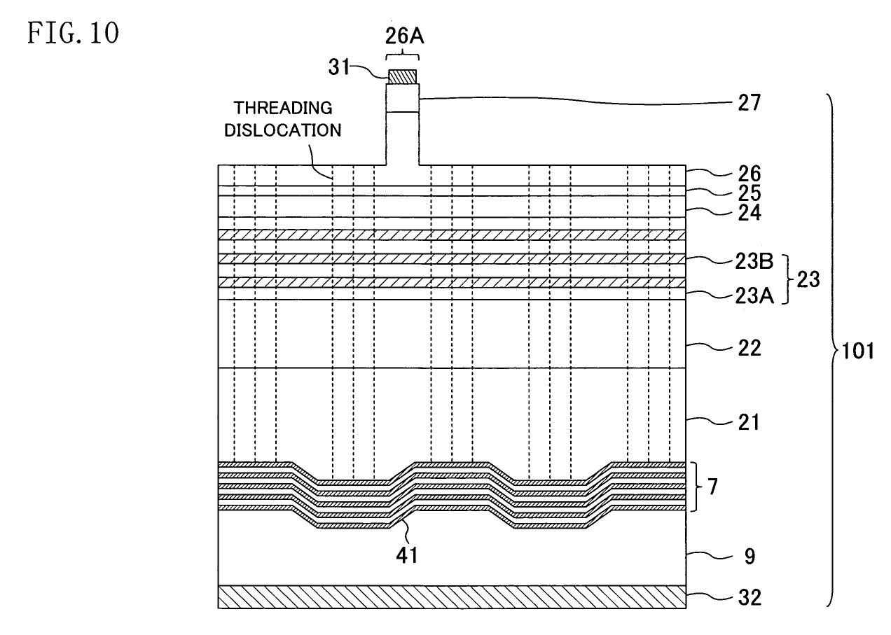

Embodiment 2 of the invention will now be described with reference to the accompanying drawing. FIG. 10 is a cross-sectional view of a semiconductor device according to Embodiment 2. As shown in FIG. 10, the semiconductor device of this embodiment is a semiconductor laser diode. In this semiconductor device, a semiconductor superlattice layer 7 and a semiconductor multilayer 101 are successively formed on a crystal growing substrate 9 of n-type Si.

The crystal growing substrate 9 has a one-dimensional periodic structure in the form of periodically formed recesses. As the one-dimensional periodic structure, recesses with a depth of 5 μm may be formed, for example. In the semiconductor device of this embodiment, there is no need to form a photonic crystal by a semiconductor superlattice layer 7. When the width at the inclined part (a step portion 41) of each recess is set equal to or larger than a part serving as a waveguide (with a width of approximately 2 μm), such as a ridge strip or the like of the semiconductor laser diode, namely, equal to or larger than 2 μm, the threading dislocation density is lowered in the active layer of the waveguide. Accordingly, the crystal growing substrate 9 device may not have the periodical structure of the recesses.

The semiconductor superlattice layer 7 includes twenty pairs each of a thin film of Si-doped AlN with a thickness of 5 nm and a thin film of Si-doped GaN with a thickness of 25 nm stacked on the crystal growing substrate 9. Each thin film included in the semiconductor superlattice layer 7 is formed along the recesses of the crystal growing substrate 9. Thus, the semiconductor superlattice layer 7 is provided with periodic concave-convex shapes resulting from transfer of the two-dimensional periodic structure of the crystal growing substrate 9.

The semiconductor multilayer 101 includes an n-type contact layer 21 made of GaN and having a thickness of 5 μm, an n-type cladding layer 22 made of Al_{0.05}Ga_{0.95}N and having a thickness of 1 μm, a light emitting layer 23 with a thickness of 29 nm, a guide layer 24 made of undoped GaN and having a thickness of 0.1 μm, a p-type electron overflow suppressing layer 25 made of Al_{0.2}Ga_{0.8}N and having a thickness of 10 nm, a p-type cladding layer 26 with a thickness of 0.1 μm, and a p-type contact layer 27 made of GaN and having a thickness of 50 nm. The light emitting layer 23 is a multiple quantum well layer including three pairs each of a well layer 23A of undoped In_{0.15}Ga_{0.85}N with a thickness of 3 nm and a barrier layer 23B of undoped In_{0.02}Ga_{0.98}N with a thickness of 5 nm. In these layers, an n-type layer is doped with Si and a p-type layer is doped with Mg.

A part of the p-type cladding layer 26 and a part of the p-type contact layer 27 are removed by etching so as to form a ridge stripe 26A. A P electrode 31 made of a multilayered film of Pd and Pt is formed on the ridge stripe 26A. An N electrode 32 made of a multilayered film of Ti and Al is formed on a surface of the crystal growing substrate 9 opposite to the semiconductor superlattice layer 7 (i.e., the back surface).

In the semiconductor laser diode of this embodiment, the semiconductor multilayer 101 including the light emitting layer 23 is formed on the semiconductor superlattice layer 7 having the periodic concave-convex shapes. Therefore, in a region of the semiconductor multilayer 101 formed on or above a step portion 41 of the concave-convex shapes as shown in FIG. 10, the threading dislocation density is smaller than in another region. Therefore, a light emitting layer 23 with few defects can be realized. Furthermore, the ridge stripe 26A for confining a current is formed above the step portion 41 with a low threading dislocation density, so as to reduce non-radiative recombination and light absorption in threading dislocations, thereby improving the quantum efficiency of the semiconductor laser diode.

### Embodiment 3

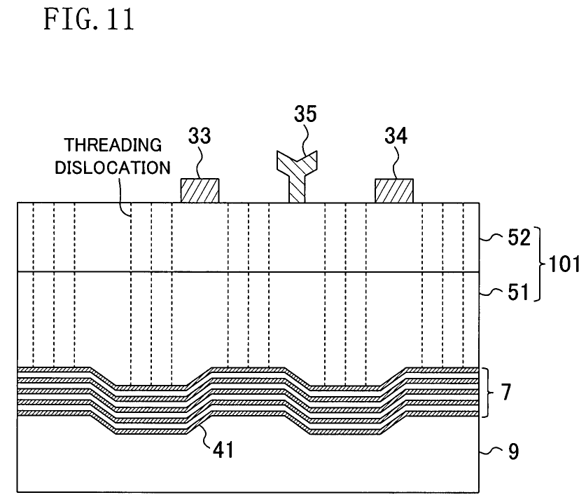

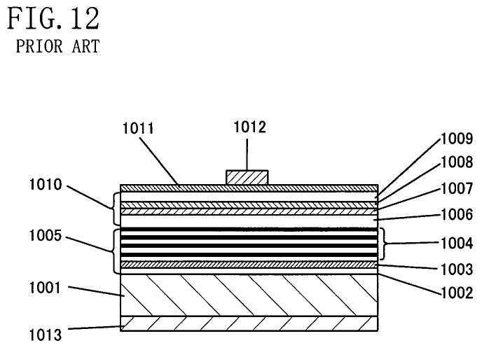

Embodiment 3 of the invention will now be described with reference to the accompanying drawing. FIG. 11 is a cross-sectional view of a semiconductor device according to Embodiment 3. As shown in FIG. 11, the semiconductor device of this embodiment is a field effect transistor. In this semiconductor device, a semiconductor superlattice layer 7 and a semiconductor multilayer 101 are successively formed on a crystal growing substrate 9 made of n-type Si.

The crystal growing substrate 9 has a one-dimensional periodic structure in the form of periodically formed recesses. As the one-dimensional periodic structure, recesses with a depth of 200 nm may be formed, for example. In the semiconductor device of this embodiment, there is no need to form a photonic crystal by a semiconductor superlattice layer 7. When the width at the inclined part (a step portion 41) of each recess is set equal to or larger than the gate length (approximately 0.1 to 1 μm) in the field effect transistor, namely, equal to or larger than 0.2 μm, the threading dislocation density is lowered at the gate thereof. Accordingly, the crystal growing substrate 9 may not have the periodical structure of the recesses.

The semiconductor superlattice layer 7 includes twenty pairs each of a thin film of undoped AlN with a thickness of 5 nm and a thin film of undoped GaN with a thickness of 25 nm stacked on the crystal growing substrate 9. Each thin film included in the semiconductor superlattice layer 7 is formed along the recesses of the crystal growing substrate 9. Thus, the semiconductor superlattice layer 7 is provided with periodic concave-convex shapes resulting from transfer of the two-dimensional periodic structure of the crystal growing substrate 9.

The semiconductor multilayer 101 includes a buffer layer 51 made of undoped GaN and having a thickness of 5 μm and a cap layer 52 made of Si-doped Al_{0.1}Ga_{0.9}N and having a thickness of 0.2 μm.

A drain electrode 33 and a source electrode 34 both made of a multilayered film of Ti and Al are formed on the cap layer 52 to be spaced from each other. A gate electrode 35 made of a multilayered film of Pd and Au is formed between the drain electrode 33 and the source electrode 34.

In the field effect transistor of this embodiment, the semiconductor multilayer 101 is formed on the semiconductor superlattice layer 7 having the periodic concave-convex shapes. Therefore, in a region of the semiconductor multilayer 101 formed on or above a step portion 41 of the concave-convex shapes as shown in FIG. 11, the threading dislocation density is smaller than in another region. Accordingly, the electron mobility can be improved in a channel formed on the interface between the cap layer 52 and the buffer layer 51.

Furthermore, the drain electrode 33, the source electrode 34 and the gate electrode 35 are formed above the step portions 41 having a low threading dislocation density. Therefore, the contact resistance between the drain electrode 33/the source electrode 34 and the channel can be lowered. Furthermore, the channel can be efficiently controlled by the gate electrode 35.

Although a hetero-junction field effect transistor is exemplified in this embodiment, similar effects can be attained in a field effect transistor of any type by lowering the threading dislocation density in a region where a channel is formed. Also, similar effects can be attained not only in a field effect transistor but also in a Schottky diode and a bipolar transistor.

In each of the embodiments described above, the two-dimensional periodic structure provided in the crystal growing substrate and the two-dimensional periodic structure transferred in the semiconductor superlattice layer have the hexagonal symmetrical arrangement. However, recesses or projections are two-dimensionally periodically arranged in the two-dimensional periodic structure, and similar effects can be attained in the case where recesses or projections are periodically arranged in the form of, for example, a square to be tetragonally asymmetric. Furthermore, the depth of a recess or the height of a projection is approximately 50 nm through 200 nm. Moreover, the plane shape of a recess or a projection is not limited to a circular shape but may be a polygonal shape. Also, the cross-sectional shape of a projection is not limited to a column-shape but may be a trapezoidal shape.

Although the crystal growing substrate is made of Si in each embodiment, any substrate can be used as far as a semiconductor superlattice layer and a semiconductor multilayer can be formed thereon, and the substrate can be appropriately selected in accordance with the materials of the semiconductor superlattice layer and the semiconductor multilayer. For example, the substrate may be made of gallium arsenide or indium phosphorus instead of Si. Also, the holding substrate may be any substrate and may be made of gallium arsenide or indium phosphorus instead of Si.

As described so far, the semiconductor device of the present invention is useful as an inexpensive semiconductor device with good characteristics.

The description of the embodiments of the present invention is given above for the understanding of the present invention. It will be understood that the invention is not limited to the particular embodiments described herein, but is capable of various modifications, rearrangements and substitutions as will now become apparent to those skilled in the art without departing from the scope of the invention. Therefore, it is intended that the following claims cover all such modifications and changes as fall within the true spirit and scope of the invention.

What is claimed is:

1. A semiconductor device comprising:
a semiconductor superlattice layer having periodic concave-convex shapes and made of a plurality of thin films stacked on one another and having bent portions in accordance with the concave-convex shapes; and
a semiconductor multilayer covering the concave-convex shapes and including an active layer.

2. The semiconductor device of claim 1,
wherein a threading dislocation density is lower in a region of the semiconductor multilayer covering a step portion of the concave-convex shapes than in another region.

3. The semiconductor device of claim 1,
wherein a threading dislocation density distribution is periodic in the semiconductor multilayer.

4. The semiconductor device of claim 1,
wherein the active layer is a light emitting layer of a light emitting diode.

5. The semiconductor device of claim 1,
wherein the active layer is a light emitting layer of a semiconductor laser diode.

6. The semiconductor device of claim 1,
wherein the active layer is a channel layer of a field effect transistor or a base layer of a bipolar transistor.

7. The semiconductor device of claim 1, further comprising a crystal growing substrate having recesses or projections according to the concave-convex shapes,
wherein the semiconductor superlattice layer is formed on the crystal growing substrate.

8. The semiconductor device of claim 7,
wherein the crystal growing substrate is made of silicon, gallium arsenide or indium phosphorus.

9. The semiconductor device of claim 1, further comprising a holding substrate,
wherein the semiconductor multilayer is bonded to the holding substrate on a surface thereof opposite to a surface on which the semiconductor superlattice layer is formed.

10. The semiconductor device of claim 9,
wherein the holding substrate is made of silicon, gallium arsenide or indium phosphorus.

11. The semiconductor device of claim 9,
wherein the active layer is a light emitting layer, and
the concave-convex shapes of the semiconductor superlattice layer diffract light emitted from the light emitting layer for radiating diffracted light to outside of the semiconductor superlattice layer.

12. The semiconductor device of claim 11,
wherein the concave-convex shapes are arranged in the form of a two-dimensional periodic structure.

13. The semiconductor device of claim 11, further comprising a reflection electrode formed between the semiconductor multilayer and the holding substrate,
wherein the reflection electrode has reflectance larger than reflectance obtained on an interface between a material for the semiconductor multilayer and a material for the holding substrate.

14. The semiconductor device of claim 13,
wherein the reflection electrode is made of gold, platinum copper, silver, rhodium or palladium, or a multilayered film including two or more of gold, platinum, copper, silver, rhodium and palladium.

15. The semiconductor device of claim 11,
wherein the light emitting layer is made of a nitride semiconductor.

16. A method for fabricating a semiconductor device comprising the steps of:
(a) preparing a substrate having periodic recesses or projections;
(b) forming a semiconductor superlattice layer on the substrate along the recesses or projections; and
(c) forming a semiconductor multilayer including an active layer on the semiconductor superlattice layer.

17. The method for fabricating a semiconductor device of claim 16, further comprising a step (d) of removing the substrate after the step (c).

18. The method for fabricating a semiconductor device of claim 16,
wherein a threading dislocation density is lower in a region of the semiconductor multilayer formed over a step portion of the recesses or projections than in another region in the step (c).
